(19) United States
(12) Patent Application Publication
(10) Pub. No.: US 2006/0013131 A1
(43) Pub. Date: Jan. 19, 2006

(54) Selecting downloading site of data element in telecommunications system

(76) Inventors: Jakke Makela, Turku (FI); Marko T. Ahvenainen, Ruutana (FI)

Correspondence Address: PERMAN & GREEN, 425 POST ROAD, FAIRFIELD, CT, 06824, US

(21) Appl. No.: 11/153,242

(22) Filed: Jun. 15, 2005

(30) Foreign Application Priority Data
Jun. 30, 2004 (FI) 20040909

(51) Int. Cl. G01R 31/08

(52) U.S. Cl. 370/229; 370/252

(57) ABSTRACT

A method for selecting the downloading site of at least one downloadable data element in a telecommunications system comprising at least one telecommunications network, at least two terminals that have established a telecommunications link with each other through the telecommunications network, and a unit comprising at least one data element, the method comprising defining a set of consumption parameters, the values of which change as a function of downloading said data element, defining for the terminals downloading function values as functions of said consumption parameters, defining for said terminals a downloading order in such a manner that a terminal having the lower downloading function value precedes a terminal having a higher downloading function value, and downloading said data element from the unit comprising data elements into the first terminal in the downloading order; a terminal, telecommunications system, network element, and computer program product.

### FIELD OF THE INVENTION

The invention relates to optimizing data transmission in a telecommunications system, and especially to selecting a downloading site for at least one downloadable data element in a telecommunications system.

### BACKGROUND OF THE INVENTION

Today, ever faster and more versatile user applications that are low in operating costs are required of wireless terminals. The terminal shall be capable of processing large amounts of data, since a mobile phone, for instance, is no longer used only for talking, but also as an Internet browser and web game machine. Numerous user applications require from the terminal more and more memory, a faster data transmission rate, and a more efficient optimization of energy consumption. In addition, with the increased use of user applications, the optimization of their operating costs is becoming more and more important.

Interfaces between terminals and telecommunications networks are essential for the ability of a terminal to both receive and transmit information. Large amounts of data are generally transferred over interfaces, so the small bandwidth of some of the interfaces, which slows down and limits data transmission significantly, is a problem in the prior-art solutions. Another problem is that the data transmission rates of telecommunications networks differ greatly from each other. A local area network typically has a higher data transmission rate than a remote network, but this is not always so. In addition, the data transmission rates between different local area networks and remote networks are different, and the data transmission rate of one network can even be different in its various parts. Thus, there may be several data transmission rates along one data transmission route. A low data transmission rate in one section of the route may thus delay data transmission significantly, even though the data transmission rate was high in some of the other sections. For instance, downloading data from the Internet to a terminal may take an unreasonably long time because of one slow section of the route.

Another problem with solutions according to the prior art is that the energy consumption resulting from data transmission may also vary considerably in different sections of the data transmission route. Data transmission in a remote network typically consumes more energy than in a local area network, but this is not always so. There are also differences in energy consumption between different remote networks, as there are between local area networks. In addition, there may be differences in energy consumption within the networks.

A further problem with a prior-art solution is that data transmission may be expensive for the user of the terminal. Data transmission costs vary between different networks and within networks in the same manner as the above-mentioned data transmission rates and energy consumptions. Data transmission in a local area network is typically less expensive than in a remote network, but this is not always so.

Published patent FI 20,022,116 discloses a method for downloading files or parts thereof from a unit containing files over an interface to a data processing unit, in which method the files or parts thereof that will most probably be needed are downloaded. However, the solution of the publication has several drawbacks: downloading the data may be very slow because of the data transmission rates of telecommunications networks; energy consumption may limit the number of downloaded files, because the publication presents limiting energy consumption only in such a manner that the downloading is stopped when the energy consumption due to the downloading exceeds the highest allowed energy consumption; energy consumption may be high, since the publication also discloses a solution, in which energy consumption is not taken into consideration when downloading files; and downloading may be expensive for the user, since the downloading is done without optimizing the data transmission costs. A further drawback is that the publication discloses downloading data between only two units, such as terminals.

### BRIEF DESCRIPTION OF THE INVENTION

A procedure has now been developed, with which the drawbacks of the above-mentioned problems can be reduced. As different aspects of the invention, a method, system, terminal, network element, and computer program product are presented, which are characterized by what is stated in the independent claims. Preferred embodiments of the invention are disclosed in the dependent claims.

The invention is based on the idea that a telecommunications system comprises at least one telecommunications network, at least two terminals that have established a connection to each other over the telecommunications network, and a unit comprising at least one data element which in this context refers to a file, a part thereof, or any element comprising data. In this context, the unit comprising the data element refers in turn to a server, terminal, or any unit adapted to store data. The data element selection procedure of the invention defines a set of consumption parameters, the values of which change as a function of the downloading of the data element; values of a downloading function for the terminals as functions of the consumption parameters; and a downloading order for the terminals in such a manner that the terminal having the lower downloading function value precedes the terminal having the higher downloading function value. At least one data element is downloaded from the unit comprising data elements to the first terminal of the downloading order.

An essential advantage of the arrangement of the invention is that the consumption resulting from downloading data from a unit comprising data to a terminal can be optimized by the selection of the data transmission route.

According to one embodiment of the invention, at least one terminal is arranged to establish a second telecommunications link over a second telecommunications network. This permits the downloading of data elements from a wider item selection outside the local area network, such as from the Internet.

According to one embodiment of the invention, at least one consumption parameter shows the energy consumption resulting from downloading at least one data element to terminals. One advantage is then that the energy consumption can be optimized by selecting the most suitable data transmission route.

According to one embodiment of the invention, at least one consumption parameter shows the downloading time resulting from downloading at least one data element to terminals. One advantage is then that the downloading time can be optimized by selecting the most suitable data transmission route.

According to one embodiment of the invention, at least one consumption parameter shows the downloading charge resulting from downloading at least one data element to terminals. One advantage is then that the downloading charge can be optimized by selecting the most suitable data transmission route.

According to one embodiment of the invention, the access probabilities of at least two data elements are defined, the access probabilities showing the probabilities with which the data elements are accessed, a transmission order is established for the data elements as a function of the access probabilities, and the data elements are downloaded to the terminal in the transmission order of the data elements. One advantage is then that the arrangement permits a fast downloading of the data elements that are most probably needed into the terminal, whereby bandwidth is not wasted in transmitting unnecessary data. The arrangement is thus useful especially when slow interfaces are used. Another advantage is also that the arrangement permits the downloading of the data elements that are most probably needed into a data processing unit in such a manner that several data elements can be transferred with the same energy consumption or that the energy consumption resulting from data transmission can be reduced. Yet another advantage is also that by downloading only the data elements that are most probably needed over a suitable data transmission route into the terminal, any extra costs to the user remain low.

According to one embodiment of the, invention, the access probabilities of at least two data elements are defined, the access probabilities showing the probabilities with which the data elements are accessed, the energy consumption resulting from downloading of the elements are also defined, a transmission order is formed for the data elements as a function of the access probabilities, a value is defined for the maximum energy consumption which indicates the highest allowed energy consumption resulting from downloading of the data elements, and the data elements are downloaded into the terminal in the transmission order of the data elements, and at the same time, the total energy consumption from the downloading is defined until the value of the total energy consumption exceeds the value of the maximum energy consumption. With the embodiment, it is possible to achieve the same advantages as with the preceding embodiment, but an additional advantage is that the arrangement makes it possible to limit the energy consumption used in downloading to a specific value.

### BRIEF DESCRIPTION OF THE FIGURES

The invention will now be described in greater detail by means of embodiments and with reference to the attached drawings, in which

FIG. 1 is a block diagram illustrating an embodiment of the invention,

FIG. 2 is a block diagram illustrating an embodiment of the invention,

FIG. 3 is a block diagram illustrating an embodiment of the invention, and

FIG. 4 is a flow chart illustrating an embodiment of the invention.

### DETAILED DESCRIPTION OF THE INVENTION

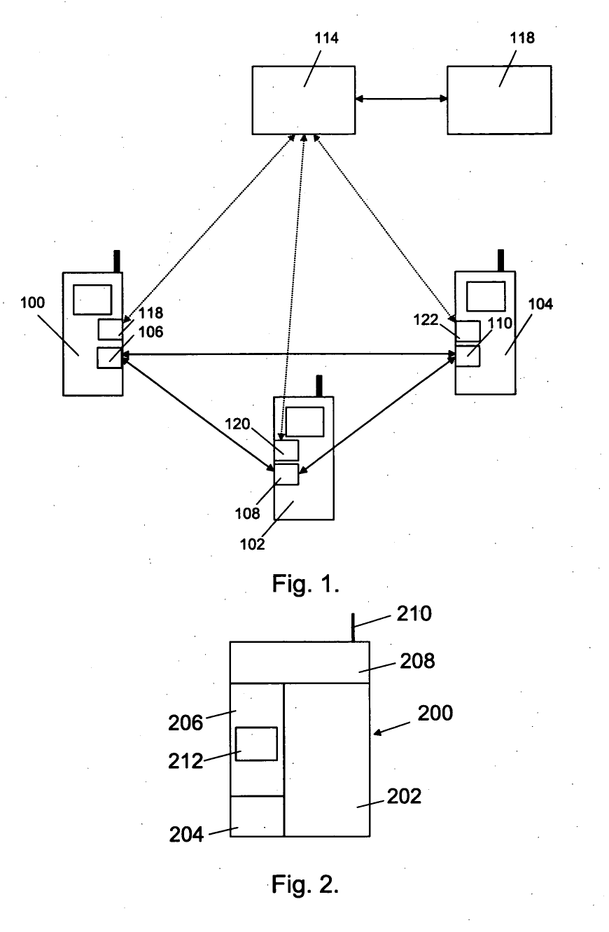

FIG. 1 shows a telecommunications system according to an embodiment of the invention. First 100, second 102, and third 104 terminals comprise connection blocks 106, 108, 110 that are arranged to establish data transmission links to each other through a local area network 112. Data transmission between the terminals 100, 102, 104 can be implemented using the Bluetooth technology, for instance, which is a wireless data transmission technology based on a short-range radio connection. The invention is not limited to this technology, but it can be used in any system that uses short-range radio frequency connections for connecting different terminals. Other technologies used in wireless data transmission include HomeRF and WLAN 802.11.

The telecommunications system of the invention also comprises a base station 114 to which the terminals 100, 102, 104 establish a telecommunications link through a public telecommunications network 116, such as mobile network, and an Internet server 118 comprising data elements, with which the terminal 100, 102, 104 have telecommunications links through the base station 114. These telecommunications links are established through network interfaces 118, 120, 122 in the terminals.

For selecting the downloading site of data elements, first a set of consumption parameters are defined, such as energy consumption, downloading time, and downloading charge, which result from downloading data elements to the terminals 100, 102, 104. The values of the consumption parameters change as a function of the downloading of the data elements. Then, downloading function values are defined for each terminal 100, 102, 104 as functions of the consumption parameters. The downloading function can be defined for instance in such a manner that all consumption parameters have the same weighting coefficient, or the effect of different consumption parameters on the downloading function can be adjusted by various weighting coefficients, whereby energy consumption, for instance, can be weighted more than the downloading time and charge. Thus, the downloading route can be selected so that energy consumption affects the selection of the downloading route proportionally more but the downloading time and charge are also taken into account. In addition, a value for the maximum consumption is defined to depict the highest allowed downloading function value.

The terminals 100, 102, 104 are arranged in a downloading order such that the terminal having the lower downloading function value precedes the terminal having the higher downloading function value. Data elements are downloaded from the Internet server 118 through the base station 114 into the first terminal of the downloading order, and at the same time, a real-time downloading function value is defined as a function of the real-time consumption resulting from downloading. The downloading and definition of the real-time downloading function value are stopped when the downloading function value exceeds the maximum consumption value. If the memory capacity of the terminal is filled up during the downloading, the downloading can be continued to the terminal next in the downloading order that has free memory capacity.

According to another embodiment, a predictive probability arrangement is implemented to the telecommunications system shown in FIG. 1. According to this embodiment, the downloading site is only selected for the data elements to be most probably needed. The set of consumption parameters, the downloading function values, and the downloading order of the terminals 100, 102, 104 are defined as in the embodiment of FIG. 1, but in this embodiment, the access probabilities of at least two data elements are also defined, which show the probabilities with which the data elements are accessed.

The definition of the access probabilities is specific for each application. If the user has downloaded a web page, for instance, it can be assumed that the user will next go to a hyperlink of the web page. Thus, there is good reason to also download the hyperlink. The access probability of data elements can also be defined on the basis of the number of visiting times at web pages through the data elements. A transmission order is established for the data elements according to the access probabilities such that the data element having the higher access probability precedes the data element having the lower access probability. The data elements are downloaded in the transmission order from the unit comprising data elements, such as the Internet server 118, into the first terminal in the downloading order.

A predictive probability arrangement is beneficial especially when the interface of the terminal 100, 102, 104 is slow in comparison with the size of the data elements. The downloading of large data elements over a slow interface on command, for instance, is very slow. The data elements to be downloaded typically have some kind of statistic or logical inter-dependency. For instance, the dependency may be the downloading of new web pages on the basis of the hyperlinks in one web page. A predictive probability arrangement can be used even when such dependencies do not exist.

According to one embodiment, a predictive probability system is implemented to the telecommunications system shown in FIG. 1 as described in the above embodiment, but the energy consumption resulting from downloading data elements and the value of the highest allowed energy consumption resulting from downloading data elements, i.e. for the maximum energy consumption, are also defined. Data elements are downloaded in the transmission order from the unit comprising data elements into the first terminal in the downloading order, and at the same time, the total energy consumption resulting from downloading data elements is defined until the value of the total energy consumption exceeds the value of the maximum energy consumption.

According to one embodiment, the values of the consumption parameter, maximum consumption, and access probabilities are defined periodically, which makes it possible to download the data elements nearly according to real-time data.

FIG. 2 is a block diagram of a wireless terminal 200 according to one embodiment, to which the invention can be applied. The wireless terminal 200 refers in this context generally to a device comprising means for implementing wireless data transmission. Such devices include devices capable of data transmission with a PLMN network, such as a GSM/GPRS network, or a third-generation network, such as a 3GPP system.

The wireless terminal 200 comprises a central processing unit 202 comprising one or more processors, memory 204, I/O system 206, and transceiver 208 arranged to transmit and receive data transmission according to different wireless data transmission protocols through an antenna 210. The transceiver 208 is thus arranged to receive data elements to the terminal 200. The required information is stored into the memory 204 of the terminal 200, which typically comprises read only memory (ROM) for storing applications controlling the central processing unit 202 and other information to be stored, and random access memory (RAM) and/or FLASH memory for use in temporarily processing data. The terminal 200 communicates with the outside world, such as other terminals, the network and user, using the I/O system 206. The user interface 212, which is part of the I/O system 206, can for instance comprise an interface, such as a display, keys, loudspeaker, and microphone, with which the terminal 200 and user can communicate with each other. The information received from different components of the terminal 200 is transmitted to the central processing unit 202 that processes the received information. The central processing unit 202 is thus arranged to define the set of consumption parameters and the values of the downloading function. In addition, the terminal 200 comprises means for detecting a suitable data transmission link.

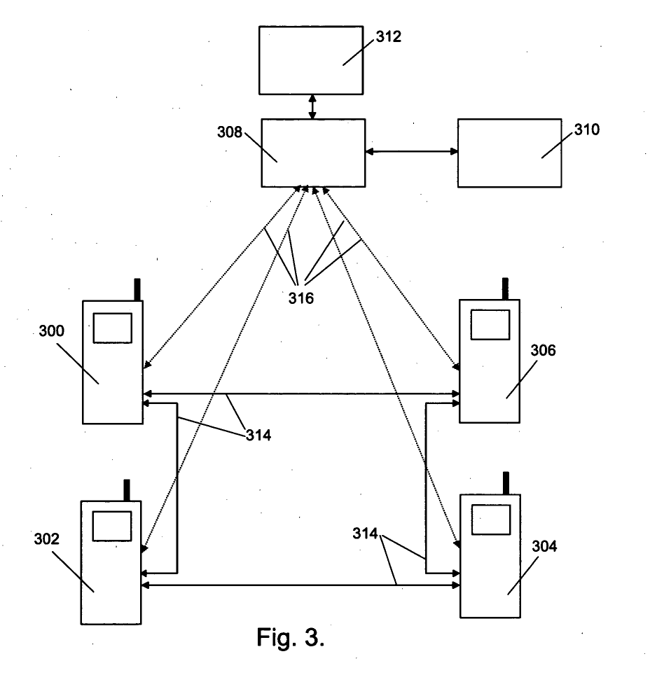

FIG. 3 shows the application of a preferred embodiment of the invention to a web game application played by terminals 300, 302, 304, 306. The terminals 300, 302, 304, 306 participating in the game have established a Bluetooth connection with each other through a telecommunications network 314 and a telecommunications link through a mobile network 316 to a base station 308 through which the terminals 300, 302, 304, 306 are connected to both a data server 312 comprising data elements and a network element server 310 that controls the downloading of the data elements from the data server 312 to at least one terminal 300, 302, 304, 306. Before downloading, the set of consumption parameters are defined, the value of the parameters changing as a function of the downloading of a data element. The downloading function values are defined for the terminals 300, 302, 304, 306 as functions of the consumption parameters. The network element 310 is arranged to define for the terminals 300, 302, 304, 306, a downloading order in such a manner that the terminal having the lower downloading function value precedes the terminal having the higher downloading function value. The network element 310 is arranged to transmit control information on the downloading order of the terminals 300, 302, 304, 306. The control information may for instance be the actual downloading order, a downloading command, or any information on the basis of which the downloading site of the data element is selected. The network element 310 can transmit the control information to the data server 312 or the first terminal in the downloading order, for instance. Data elements are downloaded from the data server 312 into the first terminal in the downloading order, from which the data elements can be distributed on to the other participants in the web game. The terminal into which the data elements are downloaded can serve as the control unit of the web game.

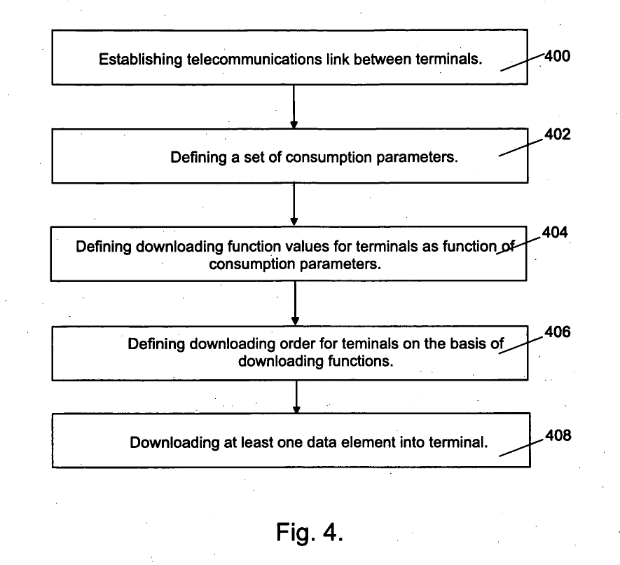

FIG. 4 shows a method according to one embodiment of the invention as a flow chart. A first terminal and a second terminal establish a telecommunications link with each other through a telecommunications network 400. Next, a set of consumption parameters 402 is defined, and downloading function values 404 are defined for the terminals as functions of the consumption parameters. A downloading order 406 is formed for the terminals in such a manner that the terminal having the lower downloading function value precedes the terminal having the higher downloading function value. At least one data element is downloaded from the unit comprising data elements into the first terminal 408 in the downloading order.

The method of the invention for selecting the downloading site of at least one downloadable data element in a telecommunications system can be implemented by a computer program product executable in the terminal 200 shown in FIG. 2, for instance. The computer program code comprises a program code for establishing a data transmission link with at least a second terminal, a program code for defining of a set of consumption parameters, the values of which change as a function of the downloading of a data element, a program code for defining a downloading function for the terminal 200 as a function of the consumption parameters, a program code for receiving a data element from a unit comprising the data element, and a program code for storing the data element into a memory in the terminal.

It is apparent to a person skilled in the art that as the technology advances, the basic idea of the invention can be implemented in many different ways. The invention and its embodiments are thus not limited to the examples and components described above, but may vary within the scope of the attached claims.

1. A method for selecting the downloading site of at least one downloadable data element in a telecommunications system comprising at least one telecommunications network, at least two terminals that have established a telecommunications link with each other through the telecommunications network, and a unit comprising said at least one data element, the method comprising:
defining a set of consumption parameters, the values of which change as a function of downloading said data element,
defining for said terminals downloading function values as functions of said consumption parameters,
defining for said terminals a downloading order in such a manner that a terminal having the lower downloading function value precedes a terminal having a higher downloading function value, and
downloading said data element from the unit comprising data elements into the first terminal in the downloading order.

2. A method as claimed in claim 1, wherein
at least one of said terminals is configured to establish a second telecommunications link through a second telecommunications network.

3. A method as claimed in claim 1, wherein
at least one of said consumption parameters represents energy consumption resulting from downloading said data element into said terminals.

4. A method as claimed in claim 1, wherein
at least one of said consumption parameters represents downloading time resulting from downloading said data element into said terminals.

5. A method as claimed in claim 1, wherein
at least one of said consumption parameters represents a downloading charge resulting from downloading said data element into said terminals.

6. A method as claimed in claim 1, the method further comprising:
defining a value for the maximum consumption that represents the highest allowed value of said downloading function.

7. A method as claimed in claim 6, the method further comprising:
downloading said data element from the unit comprising data elements into the first terminal in the downloading order, and defining for said terminal a real-time downloading function value as a function of the real-time consumption resulting from downloading, until the value of said real-time downloading function exceeds said maximum consumption value.

8. A method as claimed in claim 1, the method comprising:
downloading said data element from the unit comprising data elements into the first terminal that contains free memory capacity in the downloading order.

9. A method as claimed in claim 1, the method further comprising:
defining the access probabilities of at least two data elements, which represent the probabilities with which the data elements are accessed,
forming for said data elements a transmission order as a function of said access probabilities, and
downloading said data elements in said transmission order.

10. A method as claimed in claim 1, the method further comprising:
defining the access probabilities of at least two data elements, which represent the probabilities with which the data elements are accessed,
defining the energy consumption resulting from downloading said data elements,
forming for said data elements a transmission order as a function of said access probabilities,
defining a value for the maximum energy consumption that represents the highest allowed energy consumption resulting from said downloading, and
downloading said data elements in said transmission order, and defining the total energy consumption resulting from said downloading, until the value of the total energy consumption exceeds the value of the maximum energy consumption.

11. A method as claimed in claim 1, the method comprising:
re-defining the value of consumption parameter periodically.

12. A method as claimed in claim 6, the method comprising:
re-defining the value of at least one of the following quantities periodically:
consumption parameter
maximum consumption

13. A method as claimed in claim 9, the method comprising:
re-defining the value of at least one of the following quantities periodically:
consumption parameter
access probability.

14. A method as claimed in claim 10, the method comprising:
re-defining the value of at least one of the following quantities periodically:
consumption parameter
access probability.

15. A terminal comprising:
downloading functionality to download at least one data element in the terminal,
means for establishing a third telecommunications link to a unit comprising said data element,
means for defining a set of consumption parameters, the values of which change as a function of downloading said data element,
means for defining the downloading function values as a function of the consumption parameters, and
means for downloading said data element from the unit comprising data elements into said terminal,
the terminal being configured to establish a telecommunications link to at least a second terminal through a telecommunications network.

16. A terminal as claimed in claim 15, wherein
said terminal is configured to establish a second telecommunications link through a second telecommunications network.

17. A terminal as claimed in claim 15, wherein
at least one of said consumption parameters is configured to represent energy consumption resulting from downloading said data element into said terminal.

18. A terminal as claimed in claim 15, wherein
at least one of said consumption parameters is configured to represent downloading time resulting from downloading said data element into said terminal.

19. A terminal as claimed in claim 15, wherein
at least one of said consumption parameters is configured to represent a downloading charge resulting from downloading said data element into said terminal.

20. A terminal as claimed in claim 15, wherein
said terminal comprises means for defining the value of the maximum consumption which represents the highest allowed value of said downloading function.

21. A terminal as claimed in claim 15, wherein
said terminal comprises means for defining the value of a real-time downloading function as a function of the real-time consumption resulting from the downloading.

22. A terminal as claimed in claim 21, wherein
said terminal is configured to download said data element from the unit comprising data elements into said terminal until the value of said real-time downloading function exceeds the maximum consumption value.

23. A terminal as claimed in claim 15, wherein
said terminal also comprises:
means for defining the access probabilities of at least two data elements, which represent the probabilities with which the data elements are accessed,
means for forming for said data elements a transmission order as a function of said access probabilities, and
means for downloading said data elements in said transmission order.

24. A terminal as claimed in claim 15, wherein
said terminal also comprises:
means for defining the access probabilities of at least two data elements, which represent the probabilities with which the data elements are accessed,
means for defining energy consumption resulting from downloading-said data elements,
means for forming a transmission order for said data elements as a function of said access probability,
means for defining a value for the maximum energy consumption that represents the highest allowed energy consumption resulting from the downloading,
means for downloading said data elements in said transmission order, and
means for defining the total energy consumption resulting from the downloading.

25. A terminal as claimed in claim 15, wherein
said terminal is configured to re-define the value of consumption parameter periodically.

26. A terminal as claimed in claim 20, wherein
said terminal is configured to re-define the value of at least one of the following quantities periodically:
consumption parameter
maximum consumption

27. A terminal as claimed in claim 23, wherein
said terminal is configured to re-define the value of at least one of the following quantities periodically:
consumption parameter
access probability.

28. A terminal as claimed in claim 24, wherein
said terminal is configured to re-define the value of at least one of the following quantities periodically:
consumption parameter
access probability.

29. A telecommunications system for selecting the downloading site of at least one downloadable data element, the telecommunications system comprising:
at least one telecommunications network,
at least two terminals that have established a telecommunications link with each other through the telecommunications network,
a unit comprising said at least one data element,
means for defining a set of consumption parameters, the values of which change as a function of downloading said data element,
means for defining for said terminals downloading function values as functions of said consumption parameters,
means for defining for said terminals a downloading order in such a manner that a terminal having the lower downloading function value precedes a terminal having a higher downloading function value, and
means for downloading said data element from the unit comprising data elements into the first terminal in the downloading order.

30. A network element for a telecommunications system that comprises means for establishing a telecommunications link, wherein
said network element is configured to be in contact with terminals,
said network element is configured to receive from at least two terminals downloading function values defined as a function of the consumption parameters, the values of the consumption parameters changing as a function of downloading said parameter,
said network element is configured to define for the terminals a downloading order in such a manner that a terminal having the lower downloading function value precedes a terminal having a higher downloading function value, and
said network element is configured to transmit control information for transmitting at least one data element to the first terminal in the downloading order.

31. A computer program product for implementing downloading functionality of at least one data element in a terminal, which computer program product is executable in the terminal, the computer program comprising:
a program code for establishing a data transmission connection to at least a second terminal,
a program code for defining a set of consumption parameters, the values of which change as a function of downloading the data element,
a program code for defining a downloading function for said terminal as a function of said consumption parameters,
a program code for receiving said data element from a unit comprising the data element, and
a program code for storing said data element into the memory of the terminal.
